(19) United States
(12) Patent Application Publication
(10) Pub. No.: US 2006/0113555 A1
(43) Pub. Date: Jun. 1, 2006

(54) Light emitting diode chip with large heat dispensing and illuminating area

(76) Inventor: Chiu-Chung Yang, Taichung City (TW)

Correspondence Address: CHARLES E. BAXLEY, ESQ., 90 JOHN STREET, THIRD FLOOR, NEW YORK, NY, 10038, US

(21) Appl. No.: 11/285,799

(22) Filed: Nov. 23, 2005

(30) Foreign Application Priority Data
Dec. 1, 2004 (TW) 093136992

(51) Int. Cl. H01L 33/00

(52) U.S. Cl. 257/99

(57) ABSTRACT

A light emitting diode chip has a large area of electricity conducting material applied to each of the P pole and the N pole and the etching process does not reduce the illuminating area so that the areas of illumination and reflection are increased and the efficiency for dispensing heat is increased. The light emitting diode chip needs no encapsulation and includes functions as those flip chips and SMD.

### FIELD OF THE INVENTION

The present invention relates to a light emitting diode chip with large area of heat dispensing and illuminating area.

### BACKGROUND OF THE INVENTION

A conventional light emitting diode chip is shown in FIG. 1 and generally includes an N pole 1 and a P pole 2, and one of the two poles 1, 2 has an etching 3 which reduces the illuminating layer 4 of the chip so that the illumination is reduced which cannot meet requirement in the market. Besides, as shown in FIGS. 2 and 3, the chip 5 has a compact size and the area “A” for wiring 8 to the N pole 6 and P pole 7 is much larger than conventional light emitting diode chips so that the illuminating area is very limited. Generally, the area for wiring is around 100μ.

FIG. 2 shows a welding technique named SMD to the light emitting diode chip wherein the chip 5 has to reserve the wiring position so that the chip 5 can be connected to the base board by the wires and the base board is then electrically connected to the printed circuit board.

As shown in FIG. 3, the conventional chip has poor ability for dispensing heat, because the length “L” for the paths is tool long and the area “S” for dispensing heat is small so that the conventional light emitting diode chip has an inherent drawback of high temperature.

FIG. 4 shows that the light emitting diode chip has small area for each of the P pole and N pole, so that only tin beads 9 can be used in welding process. The chip is then welded to the base board which is welded to the printed circuit board by conventional tin paste.

The present invention intends to provide a light emitting diode chip wherein the etching process does not reduce the illuminating area so that the areas of illumination and reflection are increased and the efficiency for dispensing heat is increased.

### SUMMARY OF THE INVENTION

The present invention provides a light emitting diode chip wherein the etching process does not reduce the illuminating area and a large area of electricity conducting area is applied to each of the P pole and the N pole so that the areas of illumination and reflection are increased and the efficiency for dispensing heat is increased. The light emitting diode chip needs no encapsulation and includes functions as those flip chips and SMD.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a cross sectional view of a conventional chip;

FIG. 2 shows a SMD chip welded to a base board which is welded to a printed circuit board;

FIG. 3 shows a bottom view of another conventional chip;

FIG. 4 shows that another conventional chip is welded to a base board by tin beads and the base board is welded to a printed circuit board;

FIG. 5 is a cross sectional view to show the chip of the present invention;

FIG. 6 shows a bottom view of the chip of the present invention, and

FIG. 7 shows that the chip of the present invention is welded to a printed circuit board.

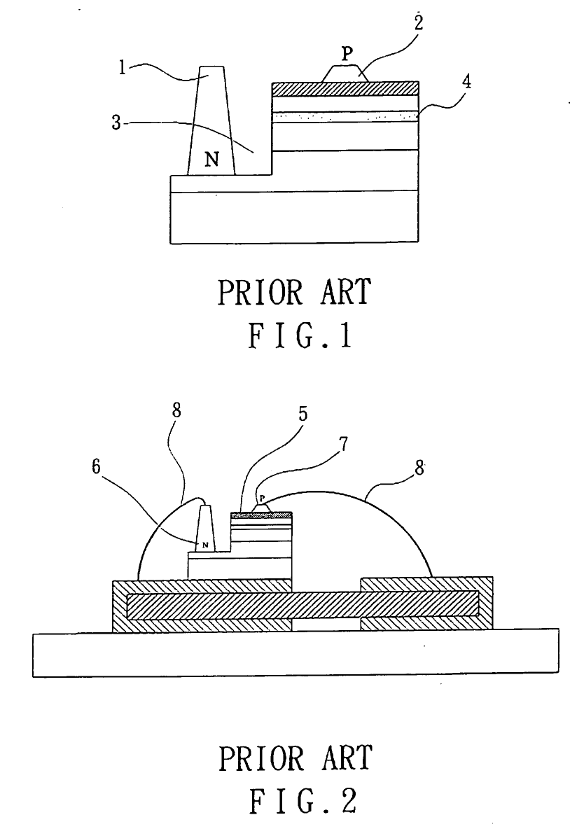

### DETAILED DESCRIPTION OF THE PREFERRED EMBODIMENT

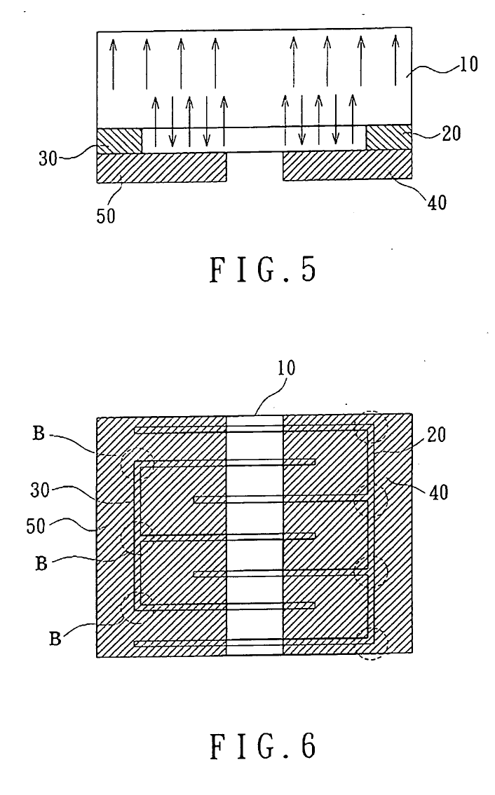

Referring to FIG. 5, the light emitting diode chip 10 has a P pole 20 and an N pole 30 on one side thereof and this side of the chip 10 is treated by an etching process. Two large areas of electricity conductive materials 40 and 50 are applied to the P pole 20 and an N pole 30 respectively. By the large areas of the of electricity conductive materials 40 and 50, the chip 10 has a large area for dispensing heat and for reflecting light with encapsulation. The areas of the P pole 20 and an N pole 30 are also enlarged. The chip 10 of the present invention includes all the functions of SMD and flip chips so that the expense for encapsulation can be reduced.

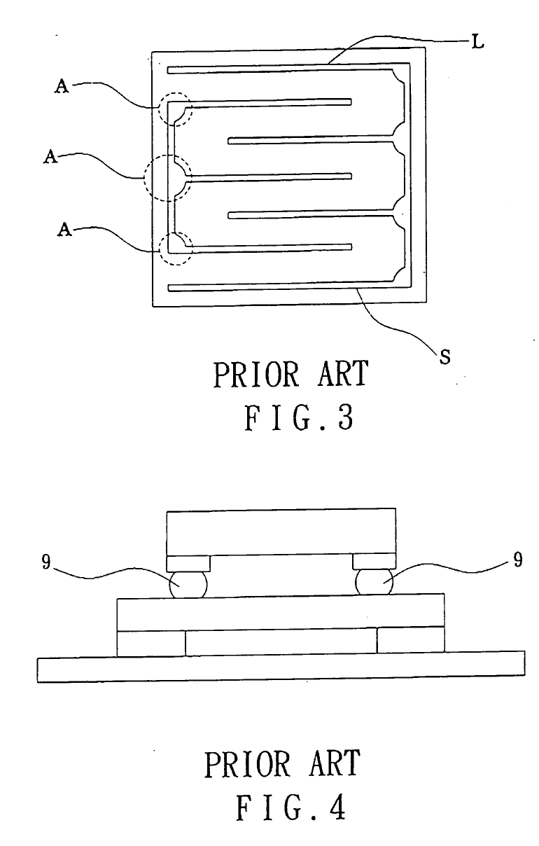

As shown in FIG. 6, the difference between the chip 10 of the present invention an the conventional chip can be seen when compared with the chip shown FIG. 3, wherein the “A” in FIG. 3 is the position for wiring so that the etching area is large. The chip of the present invention needs no wiring so that the area for etching is reduced and the area for illumination is increased. Large area of electricity conductive material 40 and 50 such as gold, silver, cupper, aluminum, tin, and alloy are applied onto the P pole 20 and the N pole 30. The electricity conductive material 40 and 50 can dispense heat and reflect light so that the chip 10 has better efficiency for dispensing heat and for reflecting light.

The conventional chips are compact and the areas of P pole and N pole are limited by the size of the chips so that gold, silver, tine beads or welding lines have to be applied to the two poles and this increases cost or expenses of manufacturing, encapsulation and welding.

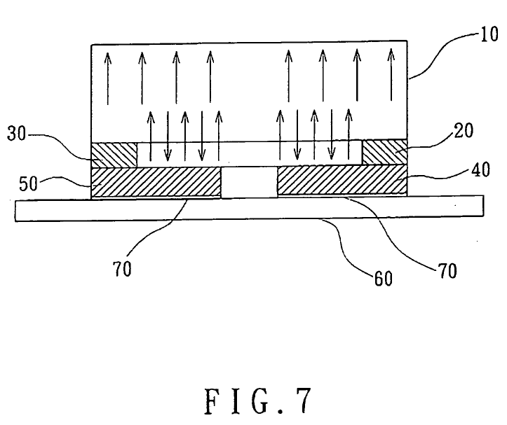

FIG. 5 shows that the chip is made with multiple layers and the P pole and the N pole are made by way of etching. A large area of electricity conductive material 40 and 50 is applied to the P pole and the N pole respectively. When the chip is welded to the printed circuit board 60, as show in FIG. 7, the electricity conductive material 40 and 50 is welded by conventional tin paste 70. The welding processes are simple and can be completed within a short period of time.

The chip of the present invention needs not base board, welding lines or welding processes and can be directly connected to the printed circuit board by conventional welding methods. The chip has all the function that SMD and flip chips without encapsulation. The area lost of the illumination layer by etching is reduced so that the illumination of the chip is increased. The large area of the electricity conductive material has good efficiency of dispensing heat and reflects light so that the chip has good illumination feature. The electricity conductive material can be easily welded to the printed circuit board.

While we have shown and described the embodiment in accordance with the present invention, it should be clear to those skilled in the art that further embodiments may be made without departing from the scope of the present invention.

What is claimed is:

1. A chip comprising:
a P pole and an N pole, each of the a P pole and an N pole having a large area of electricity conductive material connected thereto, an etching area to the area of the electricity conductive material being reduced and the electricity conductive material reflecting light, the chip having function of SMD and flip chip without encapsulation.

2. The chip as claimed in claim 1, wherein the electricity conductive material is gold, silver, copper, aluminum, tin or alloy.
